(19) United States
(12) Patent Application Publication
(10) Pub. No.: US 2010/0176365 A1
(43) Pub. Date: Jul. 15, 2010

(54) RESISTANCE VARIABLE MEMORY DEVICES AND METHODS OF FABRICATING THE SAME

(75) Inventors: Hyeyoung Park, Seongnam-si (KR); Hyun Suk Kwon, Seoul (KR); Jin Ho Oh, Seongnam-si (KR); Yong Ho Ha, Hwaseong-si (KR); Jeong Hee Park, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/684,140

(22) Filed: Jan. 8, 2010

(30) Foreign Application Priority Data
Jan. 9, 2009 (KR) 2009-0001975

(51) Int. Cl. H01L 45/00; H01L 29/18; H01L 21/02

(52) U.S. Cl. 257/3; 257/42; 438/478; 257/E45.002; 257/E29.087; 257/E21.002

(57) ABSTRACT

A resistance variable memory device includes at least one bottom electrode, a first insulating layer containing a trench which exposes the at least one bottom electrode, and a resistance variable material layer including respective first and second portions located on opposite sidewalls of the trench, respectively, where the first and second portions of the resistance variable material layer are electrically connected to the at least one bottom electrode. The device further includes a protective layer covering the resistance variable material layer within the trench, and a second insulating layer located within the trench and covering the protective layer within the trench

### PRIORITY CLAIM

A claim of priority is made to Korean Patent Application No. 2009-0001975, filed Jan. 9, 2009, the disclosure of which is incorporated herein by reference in its entirety.

### BACKGROUND

The inventive concepts described herein generally relate to memory devices. In particular, the inventive concepts relative to memory devices which include programmable volumes of resistance variable material such as, for example, so-called phase-change memory devices.

Certain types of non-volatile memory devices rely on programmable resistive characteristics of memory cells to store data. These types of memory devices are generally referred to herein as resistance variable memory cell devices, an example of which is the phase-change memory cell device.

A phase-change random access memory (PRAM), also known as an Ovonic Unified Memory (OUM), includes a phase-change material such as a chalcogenide alloy which is responsive to energy (e.g., thermal energy) so as to be stably transformed between crystalline and amorphous states. Such a PRAM is disclosed, for example, in U.S. Pat. Nos. 6,487,113 and 6,480,438.

The phase-change material of the PRAM exhibits a relatively low resistance in its crystalline state, and a relatively high resistance in its amorphous state. In conventional nomenclature, the low-resistance crystalline state is referred to as a ‘set’ state and is designated logic “0”, while the high-resistance amorphous state is referred to as a ‘reset’ state and is designated logic “1”. It is also possible, for example, to implement a “multi-bit” configuration in which two or more bits are stored in each phase change cell by programming the cell into different crystalline states having different resistivities.

The terms “crystalline” and “amorphous” are relative terms in the context of phase-change materials. That is, when a phase-change memory cell is said to be in its crystalline state, one skilled in the art will understand that the phase-change material of the cell has a more well-ordered crystalline structure when compared to its amorphous state. A phase-change memory cell in its crystalline state need not be fully crystalline, and a phase-change memory cell in its amorphous state need not be fully amorphous.

Generally, the phase-change material of a PRAM is reset to an amorphous state by joule heating of the material in excess of its melting point temperature for a relatively short period of time. On the other hand, the phase-change material is set to a crystalline state by heating the material below its melting point temperature for a longer period of time. In each case, the material is allowed to cool to its original temperature after the heat treatment. Generally, however, the cooling occurs much more rapidly when the phase-change material is reset to its amorphous state.

The speed and stability of the phase-change characteristics of the phase-change material are critical to the performance characteristics of the PRAM. As suggested above, chalcogenide alloys have been found to have suitable phase-change characteristics, and in particular, a compound including germanium (Ge), antimony (Sb) and tellurium (Te) (e.g., Ge₂Sb₂Te₅ or GST) exhibits a stable and high speed transformation between amorphous and crystalline states.

### SUMMARY

According to an aspect of the inventive concepts described herein, a resistance variable memory device is provided which includes at least one bottom electrode, a first insulating layer containing a trench which exposes the at least one bottom electrode, and a resistance variable material layer including respective first and second portions located on opposite sidewalls of the trench, respectively, where the first and second portions of the resistance variable material layer are electrically connected to the at least one bottom electrode. The device further includes a protective layer covering the resistance variable material layer within the trench, and a second insulating layer located within the trench and covering the protective layer within the trench.

According to another aspect of the inventive concepts described herein, a resistance variable memory device is provided which includes a plurality of word lines, a plurality of bit lines, and an array of resistance variable memory cells each electrically connected between a respective word line and a respective bit line. Each of the memory cells includes a resistance variable material layer located on opposite sidewalls of a trench formed in a material layer interposed between the word lines and bit lines, a protective layer covering the resistance variable material layer within the trench, and an insulating layer located within the trench and covering the protective layer within the trench.

According to yet another aspect of the inventive concepts described herein, a method of forming a resistance variable memory cell is provided which includes providing a first insulating layer which includes first and second electrodes, forming a second insulating layer on the first insulating layer, forming a trench within the second insulating layer so as to at least partially expose the first and second electrodes, and forming a resistance variable material layer within the trench such that the resistance variable material layer electrically contacts the first and second bottom electrodes and is located on opposite sidewalls and a bottom wall of the trench. The method further includes forming a protective layer over the resistance variable material layer, removing a portion of the protective layer to define spaced apart first and second protective layer portions located over the resistance variable material layer at the opposite sidewall walls of the trench, where a portion of the resistance variable material layer on the bottom wall of the trench is exposed between the first and second protective layer portions, and removing the exposed portion of the resistance variable material layer to define first and second resistance variable material layer portions of the opposite sidewalls of the trench. The method still further includes filling the trench with a third insulating layer, and forming first and second top electrodes which are electrically connected to the first and second resistance variable material layer portions.

### BRIEF DESCRIPTION OF THE DRAWINGS

The above and other aspects and features of the inventive concepts will become readily apparent from the detailed description that follows, with reference to the accompanying drawings, in which:

FIG. 1 is a circuit diagram illustrate a portion of a memory cell of a resistance variable memory device;

FIG. 2 is a perspective view of a resistance variable memory device according to an embodiment of the inventive concepts;

FIG. 3 is a schematic top view of the resistance variable memory device illustrated in FIG. 2;

FIG. 4 is a cross-sectional view take along line I-I′ of FIG. 3;

FIGS. 5A through 5I are cross-sectional views for reference in explaining a method of fabricating a resistance variable memory device according to an embodiment of the inventive concepts;

FIG. 6 is a perspective view of a resistance variable memory device according to another embodiment of the inventive concepts;

FIG. 7 is a schematic top view of the resistance variable memory device illustrated in FIG. 6;

FIG. 8 is a cross-sectional view take along line I-I′ of FIG. 7;

FIGS. 9A through 9F are cross-sectional views for reference in explaining a method of fabricating a resistance variable memory device according to an embodiment of the inventive concepts;

FIG. 10 through 17 are block diagrams illustrating a memory system and devices incorporating resistive variable memory devices according to one or more inventive concepts described herein.

### DETAILED DESCRIPTION OF EMBODIMENTS

Various example embodiments are described with reference to the accompanying drawings, where like reference numbers are used to denote like or similar elements. The inventive concepts may, however, be embodied in many different forms and should not be construed as limited to the embodiments set forth herein.

In the drawings, the relative dimensions of device layers may be exaggerated for clarity. That is, for example, the relative thicknesses and/or widths of layers may be varied from those depicted. For example, unless the description clearly indicates otherwise, if a first layer is shown as being thicker than a second layer, the two layers may instead have the same thickness or the second layer may be thicker than the first layer.

To facilitate understanding, a number of non-limiting descriptive terms may be utilized which are not intended to define the scope of the inventive concepts. For example, although the terms “first”, “second”, etc. may be used herein to describe various elements, these elements should not be limited by these terms. These terms are simply used to distinguish one element from another. For example, a first element could be termed a second element, and, similarly, a second element could be termed a first element, without departing from or limiting the scope of the inventive concepts. Likewise, the words “over”, “under”, “above”, “below”, etc. are relative terms which are not intended to limit the inventive concepts to a particular device orientation. As used herein, the term “and/or” includes any and all combinations of one or more of the associated listed items.

Further, the terminology utilized herein often makes reference to a “layer” of material. It will be understood that the inventive concepts are not limited to single-layer structures when reference is made to a layer of material. For example, an insulating layer can actually encompass multiple layers of insulating material which essentially achieve the same insulating functions as a single insulating layer of material. This same reasoning is to be applied to semiconductor and conductive regions and layers as well.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

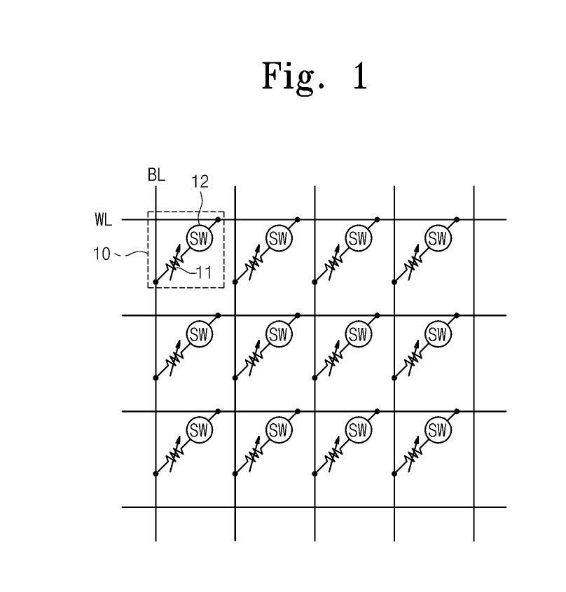

FIG. 1 is a circuit diagram illustrating an example of a portion of a memory cell array of a resistance variable memory device. As shown, the memory cell array includes a plurality of unit memory cells 10 connected between word lines WL and bit lines BL and generally located at intersection regions of the word lines WL and bit lines BL. In this example, each unit memory cell includes a resistance variable storage element 11 and a switching element 12. For example, the resistance variable storage element 11 may be a phase-change storage element, and the switching element 12 may be a diode or transistor element.

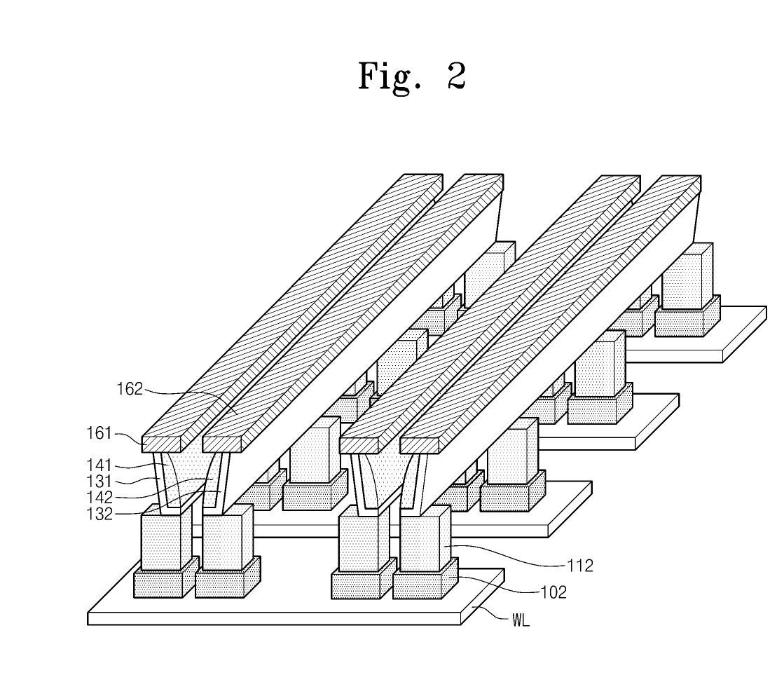

Reference is now made to FIG. 2 which is a perspective view of a resistance variable memory device according to an embodiment of the inventive concepts.

As shown in FIG. 2, the resistance variable memory device of this example includes a plurality of word lines WL, and a plurality of elongate top electrodes pairs 161/162 extending over the word lines WL in a direction substantially orthogonal the word lines WL. As described below, two resistance variable memory cells are located at each intersection region between the word lines WL and top electrode pairs 161/162.

That is, still referring to FIG. 2, the resistance variable memory device includes a pair of selection elements 102 at each intersection region between the word lines WL and top electrode pairs 161/162. One of each pair of selection elements 102 is aligned below a top electrode 161, and the other of each pair of selection elements 102 is aligned below a top electrode 162. The selection elements 102 may, for example, be implemented by diode elements and/or transistor elements. In the case where the selection element 102 is a diode element, the diode element may include an N+ doped semiconductor layer stacked over a P− doped semiconductor layer such that the N+ doped semiconductor layer is electrically connected to a word line WL. In the case where the selection element 102 is a transistor element, the transistor element may be gated to the word line WL and electrically connected in series between a bottom electrode 112 (described below) and a reference potential (e.g., a ground potential).

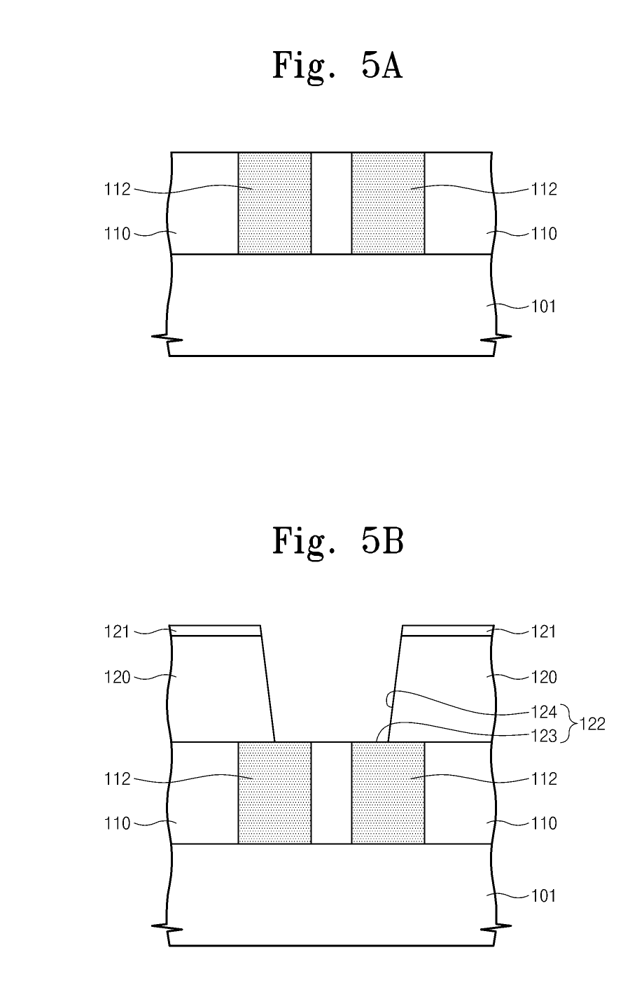

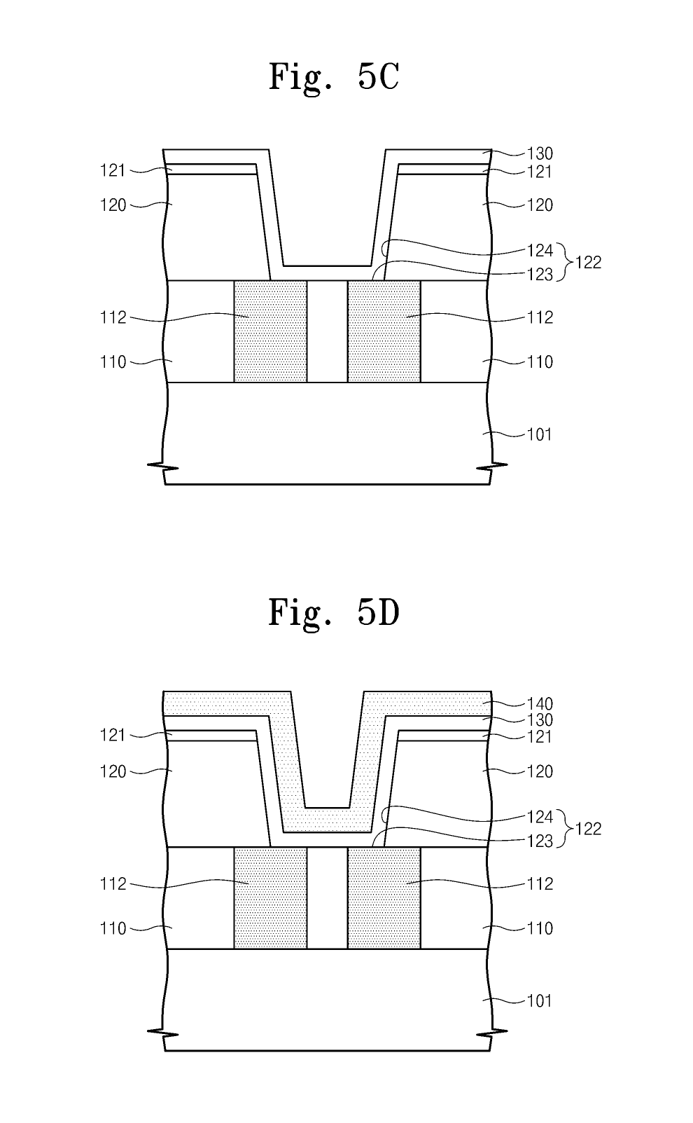

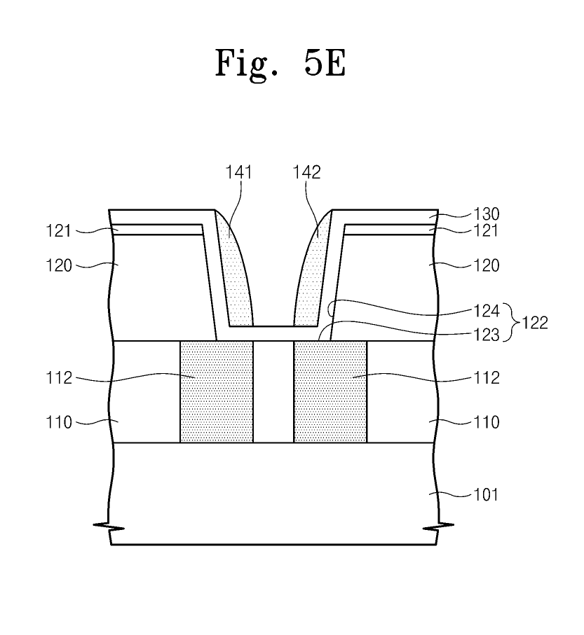

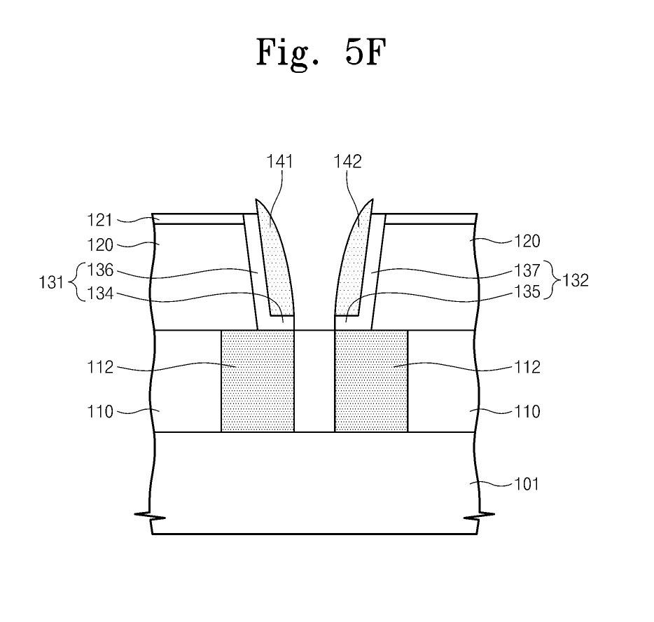

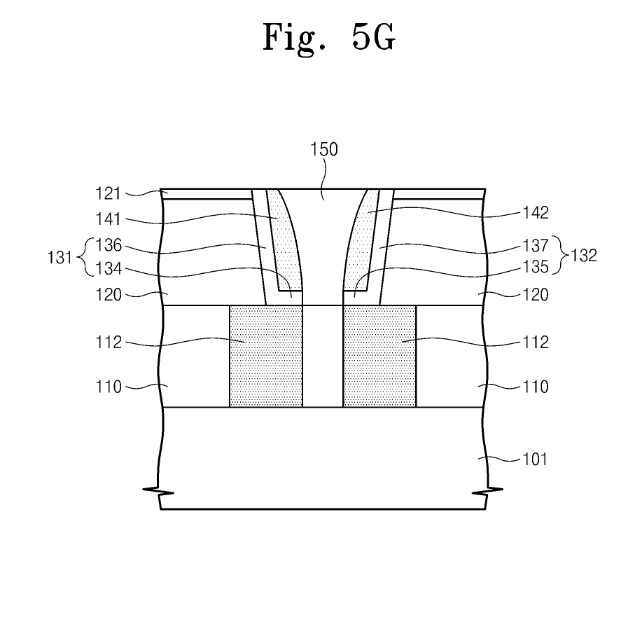

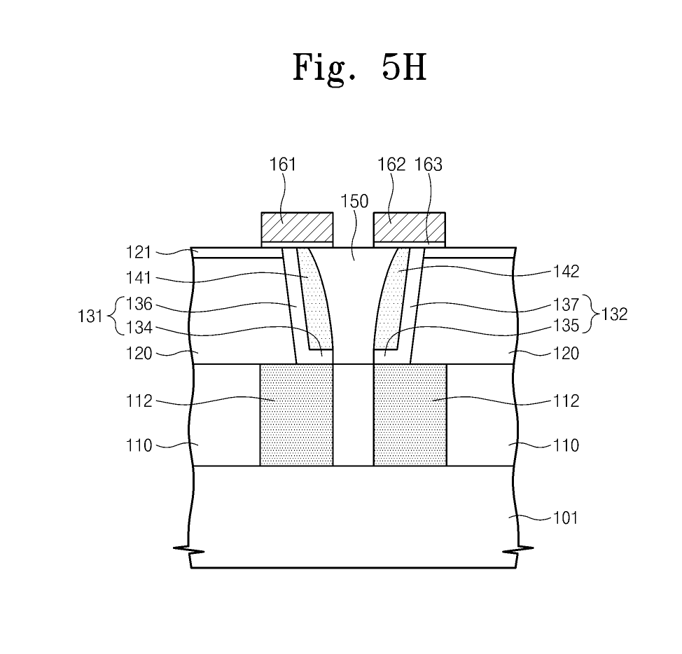

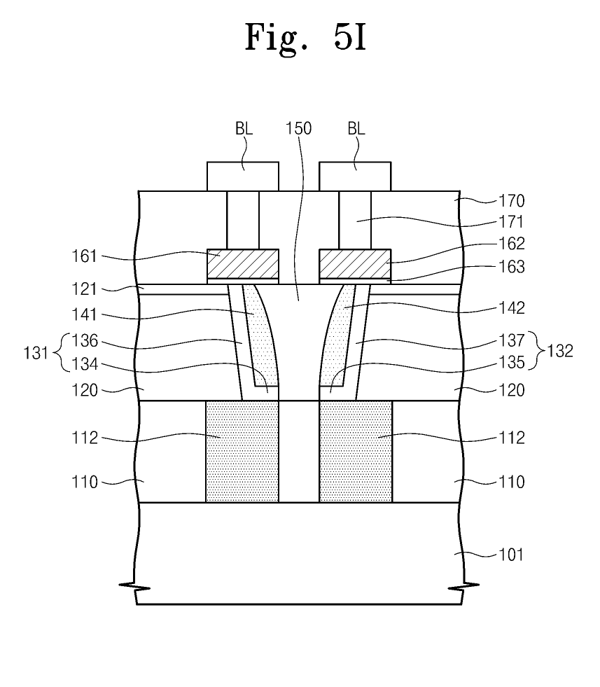

A bottom electrode 112 is located over a corresponding selection element 102 so as to be electrically connected to the corresponding selection element 102. In the example of this embodiment, each bottom electrode 112 functions in part as a heater for joule heating of a phase-change material (described later) of a corresponding memory cell. The bottom electrodes may be implemented by a single conductive layer, or by multiple conductive layers. For example, each bottom electrode 112 may include an electrically conductive layer contacting the selection element 102, and an electrically/thermally conductive layer stacked over the electrically conductive layer. Material examples of the bottom electrode 112 are presented later herein with reference to FIG. 5A.

As shown in FIG. 2, a pair of resistance variable storage patterns 131/132 is located between the respective pair of top electrodes 161/162 and a corresponding pair of bottom electrodes 112. That is, each resistance variable storage pattern 131 and 132 extends lengthwise below a corresponding top electrode 161 or 162 so as to traverse over the bottom electrodes 112 in a direction orthogonal the word lines WL (i.e., aligned in a bit line direction).

The portion of each resistance variable storage pattern 131 located above a bottom electrode 112 constitutes a storage element for storing one or more bits of data, and the portion of each resistance variable storage pattern 132 located above a bottom electrode 112 also constitutes a storage element for storing one or more bits of data. In the case where each of the resistance variable storage patterns 131 and 132 is configured of a phase-change material (e.g., GST), each storage element of the resistance variable storage patterns 131 and 132 may be programmed, for example, to either a low-resistance crystalline state (‘set’ state) storing logic “0”, or a high-resistance amorphous state (‘reset’ state) storing logic “1”. Alternately, a “multi-bit” configuration may be implemented in which two or more bits are stored in each phase change cell by programming the cell into different relative crystalline states having different resistivities.

In the example of FIG. 2, each resistance variable storage pattern 131 and 132 has a general L-shaped configuration. Further, the L-shaped configurations of each pair of storage patterns 131/132 confront one another as shown in the figure. Also shown in FIG. 2 are pairs of protective layer patterns 141/142 which respectively cover the confronting sides of each pair of resistance variable storage patterns 131/132.

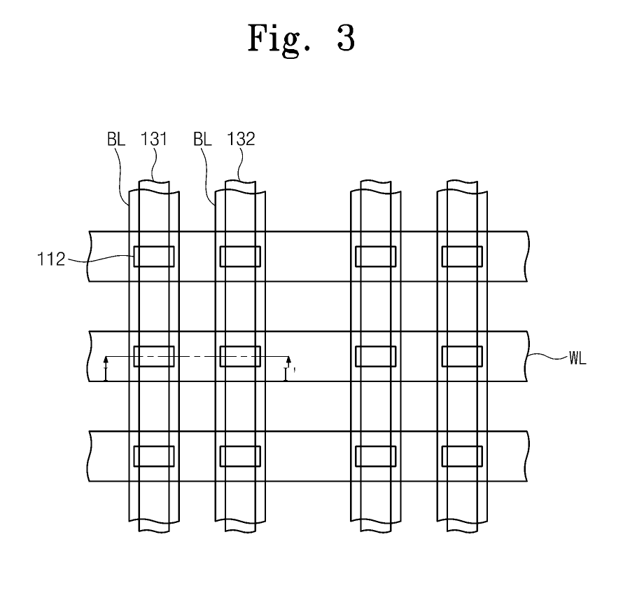

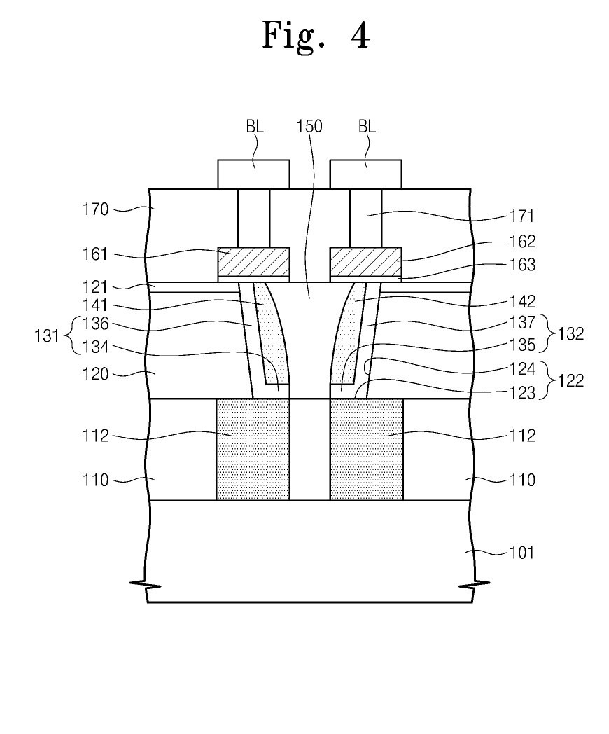

The embodiment of FIG. 2 will now be further described with reference to FIGS. 3 and 4.

FIG. 3 is a schematic top view of the resistance variable memory device illustrated in FIG. 2, and FIG. 4 is a cross-sectional view take along line I-I′ of FIG. 3.

As shown in FIG. 3, the resistance variable memory device includes a plurality of bit lines BL extending substantially orthogonal to and over a plurality of word lines WL. An array of bottom electrodes 112 is located at intersection regions between the bit lines BL and word lines WL. Further, a pair of resistance variable storage patterns 131/132 respectively extends lengthwise below adjacent bit lines BL and above the bottom electrodes 112 aligned below the length of each bit line BL.

Turning to the cross-sectional view of FIG. 4, a first interlayer insulating layer 110 is located over the upper surface of a substrate 101, and first and second bottom electrodes 112 are embedded in the first interlayer insulating layer 110 as shown. As mentioned previously, the bottom electrodes 112 may be formed of multiple conductive layers, at least one of which is functional as a joule heating element in the case where the memory device adopts a phase-change material as the resistive variable storage element. Likewise, the first interlayer insulating layer 110 may be formed of a single layer or multiple layers.

Although not shown in FIG. 4, the substrate 101 (and/or one or more layers interposed between the substrate 101 and the first interlayer insulating layer 110) includes a switching element (e.g., a diode or transistor) electrically connected to each bottom electrode 112 and to a word line (also not shown in FIG. 4).

A second interlayer insulating layer (or layers) 120 is located over the first interlayer insulating layer 110, and an etch stop layer (or layers) 121 is located over the second interlayer insulating layer 120. The second interlayer insulating layer 120 and etch stop layer 121 include a trench 122 defined therein which, according to the example of this embodiment, is aligned over an area between the adjacent bottom electrodes 112 so as to partially overlap each of the bottom electrodes 112. In FIG. 4, reference number 123 denotes a bottom wall of the trench 122, and reference number 124 denotes a sidewall of the trench 122.

First and second resistive variable storage patterns 131 and 132 are located on opposite sidewalls 124 of the trench 122 of the second interlayer insulating layer 120. In particular, the first storage pattern 131 includes a bottom wall portion 134 located on a top surface portion of the first bottom electrode 112, and a sidewall portion 136 located on the sidewall 124 of the trench 122. In the example of this embodiment, the first and second resistive variable storage patterns 131 and 132 are formed of a phase-change material such as a GST compound material.

Still referring to FIG. 4, protective layer patterns 141 and 142 respectively cover exposed surfaces of the resistive variable storage patterns 131 and 132 within the trench 122. Further, a space within the trench 122 between the protective layer patterns 141 and 142 is filled with an insulating layer 150.

A third interlayer insulating layer (or layers) 170 is located over the second interlayer insulating layer 120 as shown in FIG. 4. First and second top electrodes 161 and 162 are located within the third interlayer insulating layer 170 so as to electrically contact the respective resistive variable storage patterns 131 and 132. Also, in the example of this embodiment, the first and second top electrodes 161 and 162 each include a barrier layer 163 at the lower surface thereof.

Finally, bit lines BL are located over or within the third interlayer insulating layer 170, and contact plugs 171 extend between the bit lines BL and top electrodes 161 and 162 to electrically connect the bit lines BL and top electrodes 161 and 162.

Reference will now be made to FIGS. 5A through 5J which are cross-sectional views for use in explaining an example of a method of fabricating the resistance variable memory device described above.

As shown in FIG. 5A, a first interlayer insulating layer 110 is formed on the surface of an underlayer 101. In the example of this embodiment, the underlayer 101 is a semiconductor substrate, a silicon-on-insulator (SOI) substrate, or the like. Although not shown in FIG. 5A, the underlayer 101 includes a switching element (e.g., a diode or transistor) electrically connected to a word line (also not shown in FIG. 5A). Also in the example of this embodiment, the first interlayer insulating layer 110 is formed of SiO₂, but the other materials may be utilized instead. As non-limiting examples, the first interlayer insulating layer 110 may also be formed of BSG (boro silica glass), PSB (phosphorus silica glass), BPSG (borophosphosilicate glass), PE-TEOS (plasma-enhanced tetraethylorthosilicate), and so on.

First and second bottom electrodes 112 are formed in the first interlayer insulating layer 110 as shown in FIG. 5A. The bottom electrodes 112 may be formed, for example, by etching of contact holes in the interlayer insulating layer 110, followed by deposition of a material layer of the bottom electrodes 112, followed by planarization (e.g. CMP) of the material layer to define the bottom electrodes 112. The shape of the bottom electrodes 112 is not limited. As non-limiting examples, the bottom electrodes 112 may be columnar with a circular or rectangular cross-section, or the bottom electrodes 112 may be annular with a ring-shaped cross-section. Further, as mentioned previously, the bottom electrodes 112 may be formed of multiple layers of different materials. Non-limiting examples of the material(s) constituting the bottom electrodes include one or more of Cu, Ti, TiSiX, TiN, TiON, TiAlN, TiAlON, TiSiN, TiBN, W, WSiX, WN, WON, WSiN, WBN, WCN, Ta, TaSiX, TaN, TaON, TaAlN, TaSiN, TaCN, Mo, MoN, MoSiN, MoAlN, NbN, ZrSiN, ZrAlN, Ru, CoSiX, NiSiX and conductive carbon.

Referring to FIG. 5B, a second interlayer insulating layer 120 is deposited over the first interlayer insulating layer 110. The second interlayer insulating layer 120 may, for example, be formed of SiO₂, BSG, PSB, PBSG, PE-TEOS, and so on. An etch stop layer 121 is then patterned over the second interlayer insulating layer 120. Non-limiting examples of the etch stop layer include SiN, SiON, HfO, AlO, and so on. The etch stop layer 121, which exhibits high etch-selectivity to the second interlayer insulating layer 120, it then used as an etch mask to etch a trench 122 in the second interlayer insulating layer 120. The trench 122 is etched such that a bottom wall 123 thereof exposes at least a portion of the upper surfaces of the neighboring pair of bottom electrodes 112. Also, as shown in the figure, sidewalls 124 of the trench 122 may be formed obliquely such that a width of the trench 122 is larger at its upper opening than at the bottom wall 123.

Next, referring to FIG. 5C, a resistive variable material layer 130 is deposited which conforms to the surface of the structure shown in FIG. 5B. That is, the resistive variable material layer 130 is deposited to conformally cover the etch stop layer 121, the sidewalls 124 of the trench 122, and the bottom wall 123 of the trench 122. The resistance variable material layer 130 may be deposited, for example, by a CVD (chemical vapor deposition) or a PVD (physical vapor deposition) process. In the example of this embodiment, the resistive variable material layer is formed of a phase-change material. Non-limiting example of suitable phase-change materials include SeSbTe, GeTeAs, SnTeSn, GeTe, SbTe, SeTeSn, GeTeSe, SbSeBi, GeBiTe, GeTeTi, InSe, GaTeSe, and InSbTe. In addition, the resistance variable material layer 130 may be doped, for example, with C, N, Si and/or O.

Next, referring to FIG. 5D, a protective layer 140 is deposited on the resistance variable material layer 130. In the example of this embodiment, the protective layer 140 is deposited to conform to the topology of the resistance variable material layer 130, and thus does not completely fill the trench 122. For example, the depth of the protective layer 140 may be less than half the width of the trench in order to avoid filling the trench.

The protective layer 140 may function to prevent heat loss of a resistive variable element during operation of the fabricated resistance variable memory device. In addition, the protective layer 140 functions to protect the resistance variable material layer 130 from process damage during subsequent steps in the fabrication process. For example, the protection layer 140 may protect the resistance variable material layer 130 from etch conditions and/or oxygen exposure (i.e., oxygen diffusion) during subsequent processes.

Non-limiting examples of a material of the protective layer 140 include silicon nitride, silicon carbon nitride, carbon nitride and/or carbon. In one specific example, the protective layer 140 is formed by PE-CVD (plasma enhanced CVD) of silicon nitride at a temperature of about 380° C. to about 400° C. As described above, the resistance variable material layer 130 may be doped with C, N, Si and/or O. In this case, it is noted that the volatile temperature of the doped material is higher than that of a non-doped material.

Next, as shown in FIG. 5E, the protective layer 140 is removed except for portions thereof on the opposite sidewalls 124. That is, as shown in the figure, the protective layer 140 is partially removed to define protective layer patterns 141 and 142 on the resistance variable material layer 130 within the trench 122. The protective layer patterns 141 and 142 may be formed, for example, by subjecting the protective layer 140 to anisotropic etching.

FIG. 5E illustrates inner edges of the protective layer patterns 141 and 142 aligned with inner edges of the bottom electrodes 112. However, the embodiment is not limited in this respect.

Turning to FIG. 5F, the resistance variable material layer 130 is patterned to form resistance variable storage patterns 131 and 132. For example, this can be accomplished by subjecting the exposed portions (on the etch stop layer 121 and within the trench 122) of the resistance variable material layer 130 to anisotropic etching using the protective layer patterns 141 and 142 as an etch mask. Here, the protective layer patterns 141 and 142 may protect the resistance variable storage patterns 131 and 132 from damage during the etching process.

As a result of this etching process, the resistance variable storage pattern 131 and 132 are mirror images of one another and generally define L-shaped cross-sectional configurations beneath the respective protective layer patterns 141 and 142. In particular, the resistance variable storage pattern 131 includes a sidewall portion 136 and a bottom wall portion 134, and the resistance variable storage pattern 132 includes a sidewall portion 137 and a bottom wall portion 135.

Next, referring to FIG. 5G, the gap between the protective layer patterns 141 and 142 is filled with an insulating material 150. This can be accomplished, for example, by blanket deposition of an insulating material followed by a planarization process. Non-limiting examples of the blanket deposited insulating material include silicon oxide such as HDP (high density plasma) oxide, PE-TEOS (plasma-enhanced tetraethylorthosilicate), BPSG (borophosphosilicate glass), USG (undoped silicate glass), FOX (flowable oxide), HSQ (hydrosilsesquioxane) and SOG (spin on glass). Planarization may be achieved, for example, by CMP (chemical mechanical polishing) or by an etch-back process. In either case, the etch stop layer 121 may be utilized as a removal stop layer. Also, during planarization, any portions of protective layer patterns 141 and 142 protruding above the etch stop layer 121 (see FIG. 5F) may be removed as well to define a structure having a top planar surface.

Although not shown in the figures, the planarization process may be followed by plasma treatment using an inert gas. Non-limiting examples of the inert gas include Ar, He, Ne, Kr and/or Xe. Also, a sputtering process may be executed after planarization to remove any damaged or oxidized portions of the resistive variable layer patterns 131 and 132.

Next, referring to FIG. 5H, a barrier material layer and an electrode material layer are deposited and patterned using conventional techniques (e.g., deposition, masking and etching) to define top electrodes 161 and 162, each with a barrier layer 163. Non-limiting examples of the material of the top electrodes 161 and 162 include Ti, TiSiX, TiN, TiON, TiW, TiAlN, TiAlON, TiSiN, TiBN, W, WSiX, WN, WON, WSiN, WBN, WCN, Ta, TaSiX, TaN, TaON, TaAlN, TaSiN, TaCN, Mo, MoN, MoSiN, MoAlN, NbN, ZrSiN, ZrAlN, Ru, CoSi, NiSi, conductive carbon, and Cu.

The barrier layer 163 may function as an adhesive layer, and may also prevent inter-diffusion between the top electrodes 161 and 162 and the underlying layers, such as the underlying resistive variable layer patterns 131 and 132. Non-limiting material examples of the barrier layer 163 include TiN, TiW, TiCN, TiAlN, TiSiC, TaN, TaSiN, WN, MoN and CN.

In addition, in the case where the resistive variable layer patterns 131 and 132 are formed of a phase-change material, such as a GST (or chalcogenide) material, the barrier layer 163 can also be formed to include a phase-change material which is the same as or different than the material of the resistive variable layer patterns 131 and 132. This can have the advantage of compensating for any damage to the resistive variable layer patterns 131 and 132 that may have occurred during planarization of the insulating layer 150 described previously. For example, the barrier layer 163 can include a stacked structure of a GST material layer and a conductive layer.

Next, as shown in FIG. 5I, a third interlayer insulating layer 170 is deposited, contact plugs 171 are formed in the interlayer insulating layer 170, and conductive bit lines BL are formed so as to electrically contact the contact plugs 171. Techniques and materials that may be utilized to form these elements are well-known to those skilled in the art. As shown in FIGS. 2 and 3, the bit lines BL extend lengthwise in a direction parallel with the resistance variable layer patterns 131 and 132.

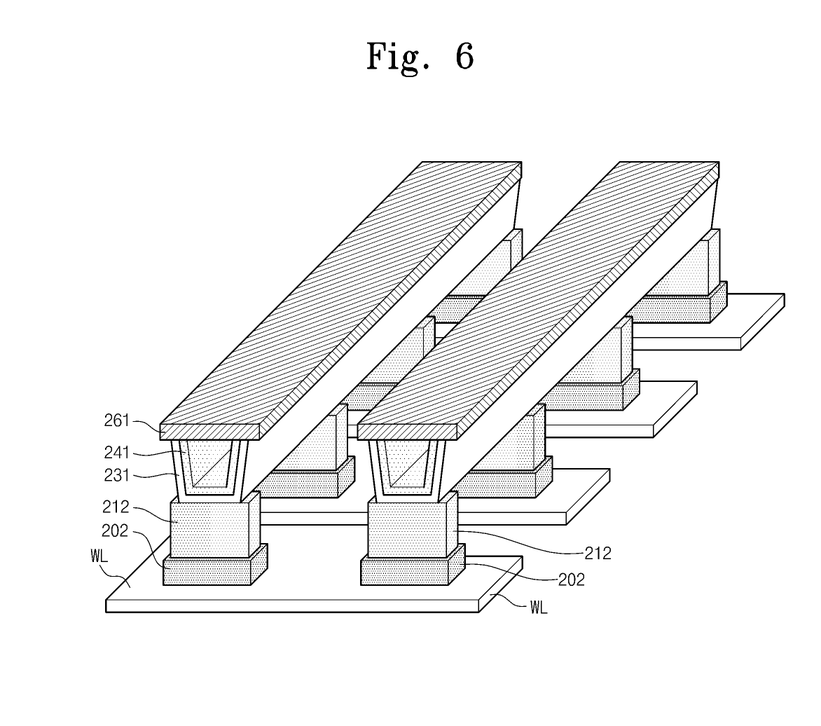

Reference is now made to FIG. 6 which is a perspective view of a resistance variable memory device according to another embodiment of the inventive concepts.

As shown in FIG. 2, the resistance variable memory device of this example includes a plurality of word lines WL, and a plurality of elongate top electrodes 261 extending over the word lines WL in a direction substantially orthogonal the word lines WL. As described below, a resistance variable memory cell is located at each intersection region between the word lines WL and top electrode 261.

That is, still referring to FIG. 6, the resistance variable memory device includes a selection element 202 at each intersection region between the word lines WL and top electrodes 261. One of each selection elements 202 is aligned below a top electrode 261. The selection elements 202 may, for example, be implemented by diode elements and/or transistor elements. In the case where the selection element 202 is a diode element, the diode element may include an N+ doped semiconductor layer stacked over a P− doped semiconductor layer such that the N+ doped semiconductor layer is electrically connected to a word line WL. In the case where the selection element 202 is a transistor element, the transistor element may be gated to the word line WL and electrically connected in series between a bottom electrode 212 (described below) and a reference potential (e.g., a ground potential).

A bottom electrode 212 is located over a corresponding selection element 202 so as to be electrically connected to the corresponding selection element 202. In the example of this embodiment, each bottom electrode 212 functions in part as a heater for joule heating of a phase-change material (described later) of a corresponding memory cell. The bottom electrodes may be implemented by a single conductive layer, or by multiple conductive layers. For example, each bottom electrode 212 may include an electrically conductive layer contacting the selection element 202, and an electrically/thermally conductive layer stacked over the electrically conductive layer. Material examples of the bottom electrode 212 are presented later herein with reference to FIG. 5A.

As shown in FIG. 6, a resistance variable storage pattern 231 is located between a respective top electrode 261 and a corresponding bottom electrode 212. That is, each resistance variable storage pattern 231 extends lengthwise below a corresponding top electrode 261 so as to traverse over the bottom electrodes 212 in a direction orthogonal the word lines WL (i.e., aligned in a bit line direction).

The portion of each resistance variable storage pattern 231 located above a bottom electrode 212 constitutes a storage element for storing one or more bits of data. In the case where each of the resistance variable storage patterns 231 is configured of a phase-change material (e.g., GST), each storage element of the resistance variable storage patterns 231 may be programmed, for example, to either a low-resistance crystalline state (‘set’ state) storing logic “0”, or a high-resistance amorphous state (‘reset’ state) storing logic “1”. Alternately, a “multi-bit” configuration may be implemented in which two or more bits are stored in each phase change cell by programming the cell into different relative crystalline states having different resistivities.

In the example of FIG. 6, each resistance variable storage pattern 231 has a general U-shaped configuration. Also shown in FIG. 6 are protective layer patterns 241 which respectively cover the inner surface of each U-shaped resistance variable storage pattern 231.

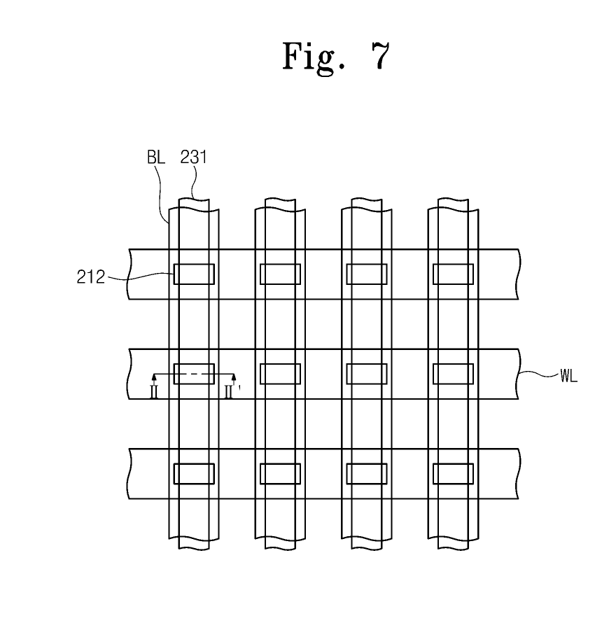

The embodiment of FIG. 6 will now be further described with reference to FIGS. 7 and 8.

FIG. 7 is a schematic top view of the resistance variable memory device illustrated in FIG. 6, and FIG. 8 is a cross-sectional view take along line I-I′ of FIG. 7.

As shown in FIG. 7, the resistance variable memory device includes a plurality of bit lines BL extending substantially orthogonal to and over a plurality of word lines WL. An array of bottom electrodes 212 is located at intersection regions between the bit lines BL and word lines WL. Further, a resistance variable storage pattern 231 extends lengthwise below each bit lines BL and above the bottom electrodes 212 aligned below the length of each bit line BL.

Turning to the cross-sectional view of FIG. 8, a first interlayer insulating layer 210 is located over the upper surface of a substrate 201, and a bottom electrode 212 is embedded in the first interlayer insulating layer 210 as shown. As mentioned previously, the bottom electrode 212 may be formed of multiple conductive layers, at least one of which is functional as a joule heating element in the case where the memory device adopts a phase-change material as the resistive variable storage element. Likewise, the first interlayer insulating layer 210 may be formed of a single layer or multiple layers.

Although not shown in FIG. 8, the substrate 201 (and/or one or more layers interposed between the substrate 201 and the first interlayer insulating layer 210) includes a switching element (e.g., a diode or transistor) electrically connected to each bottom electrode 212 and to a word line (also not shown in FIG. 8).

A second interlayer insulating layer (or layers) 220 is located over the first interlayer insulating layer 210, and an etch stop layer (or layers) 221 is located over the second interlayer insulating layer 220. The second interlayer insulating layer 220 and etch stop layer 221 include a trench 222 defined therein which, according to the example of this embodiment, is aligned over the bottom electrode 212 so as to partially overlap the bottom electrode 212. In FIG. 8, reference number 223 denotes a bottom wall of the trench 222, and reference number 224 denotes a sidewall of the trench 222.

A resistive variable storage pattern 231 is located on the opposite sidewalls 224 and the bottom wall 223 of the trench 222. In particular, the resistive variable storage pattern 231 includes a bottom wall portion 234 located on a top surface portion of the bottom electrode 212, and sidewall portion 236 located on the sidewalls 224 of the trench 122. In the example of this embodiment, the resistive variable storage pattern 231 is formed of a phase-change material such as a GST compound material.

Still referring to FIG. 8, a protective layer pattern 241 covers exposed surfaces of the resistive variable storage pattern 231 within the trench 122. Further, a space within the trench 222 is filled with an insulating layer 150.

A third interlayer insulating layer (or layers) 270 is located over the second interlayer insulating layer 220 as shown in FIG. 8. A top electrode 261 is located within the third interlayer insulating layer 270 so as to electrically contact the resistive variable storage pattern 231. Also, in the example of this embodiment, the top electrode 261 includes a barrier layer 263 at the lower surface thereof.

Finally, a bit lines BL is located over or within the third interlayer insulating layer 270, and a contact plug 271 extends between the bit line BL and top electrode 261 to electrically connect the bit line BL and top electrode 261.

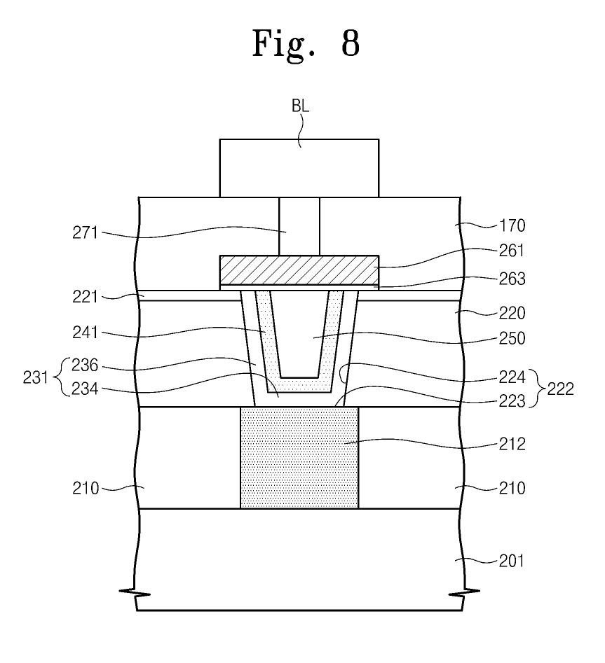

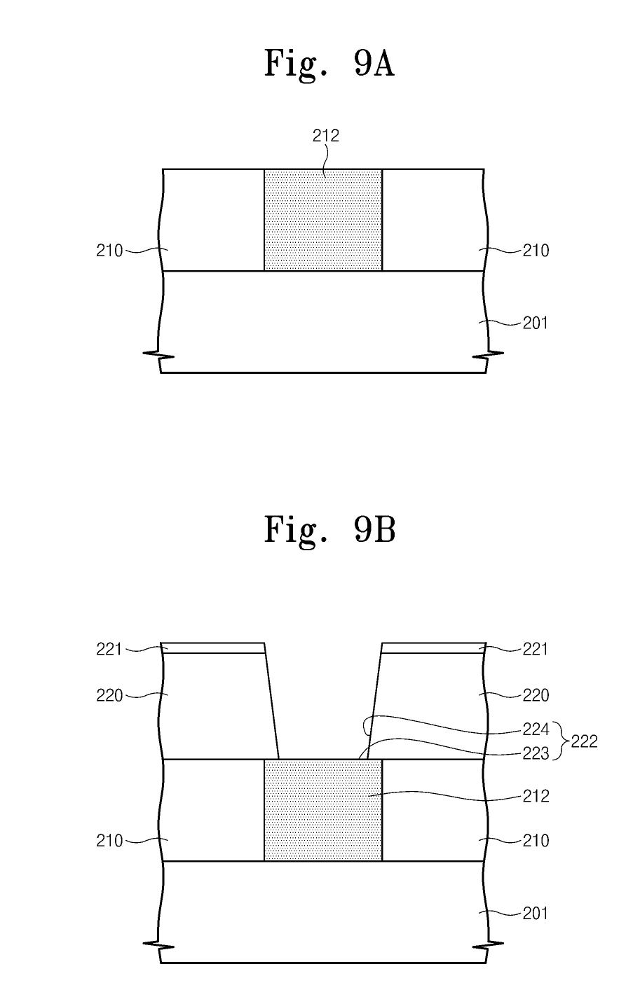

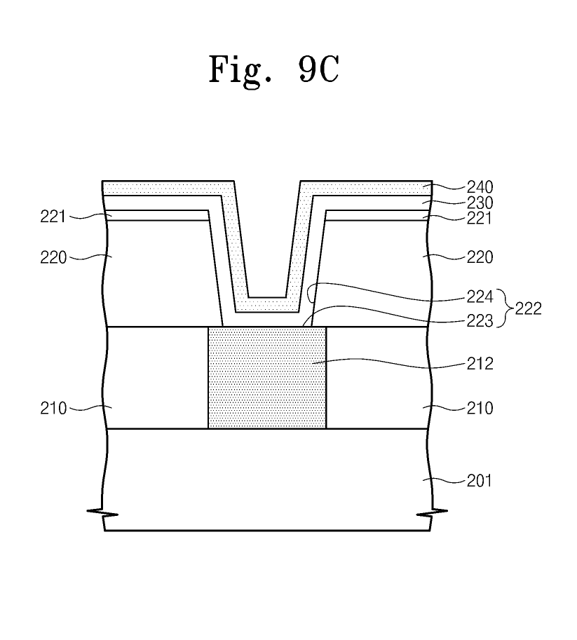

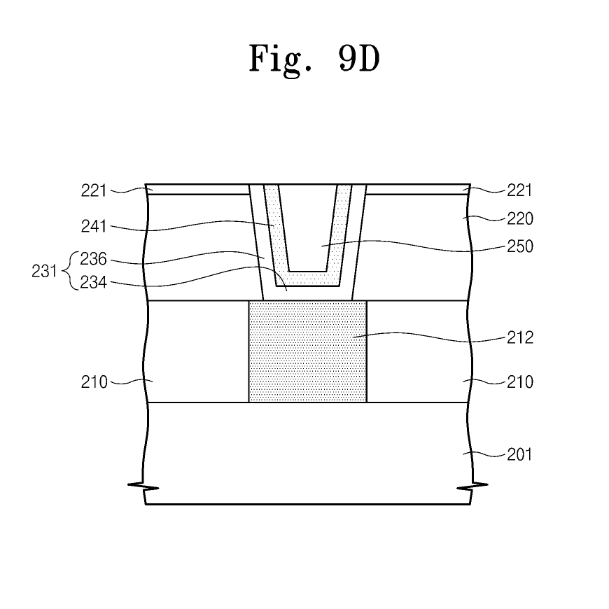

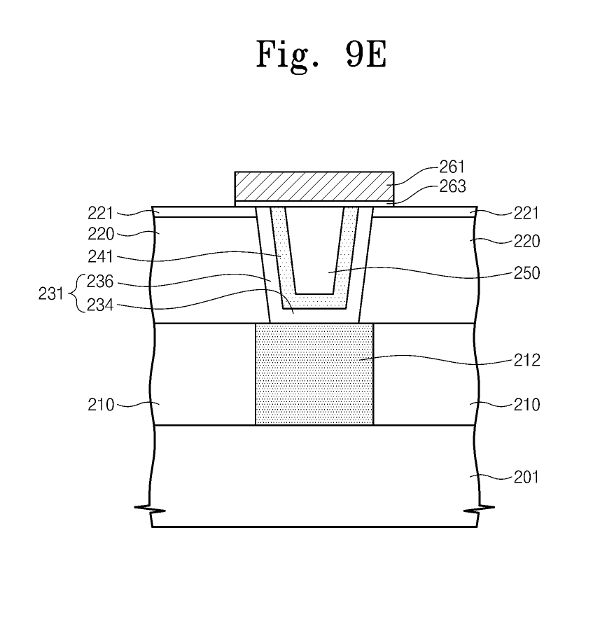

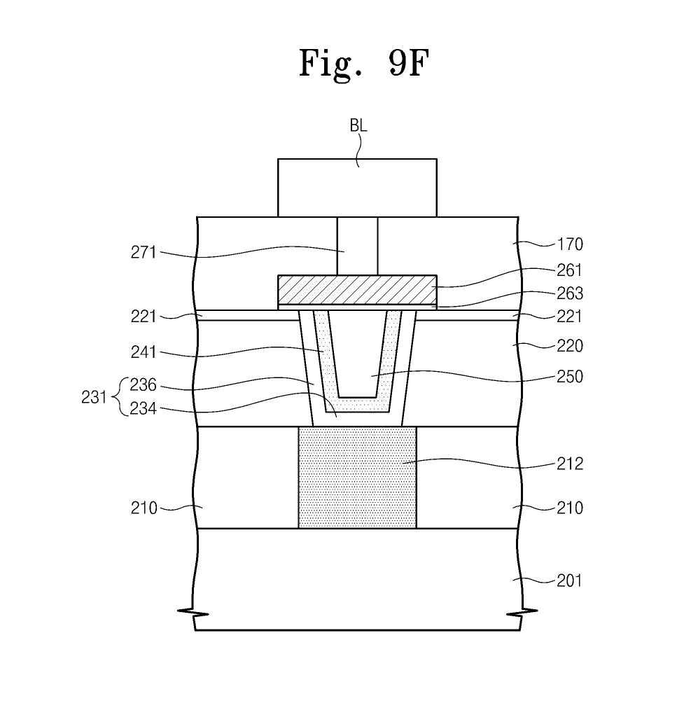

Reference will now be made to FIGS. 9A through 9F which are cross-sectional views for use in explaining an example of a method of fabricating the resistance variable memory device of FIGS. 6-8.

As shown in FIG. 9A, a first interlayer insulating layer 210 is formed on the surface of an underlayer 201. In the example of this embodiment, the underlayer 201 is a semiconductor substrate, a silicon-on-insulator (SOI) substrate, or the like. Although not shown in FIG. 9A, the underlayer 201 includes a switching element (e.g., a diode or transistor) electrically connected to a word line (also not shown in FIG. 9A). Also in the example of this embodiment, the first interlayer insulating layer 210 is formed of SiO₂, but the other materials may be utilized instead. As non-limiting examples, the first interlayer insulating layer 210 may also be formed of BSG (boro silica glass), PSB (phosphorus silica glass), BPSG (borophosphosilicate glass), PE-TEOS (plasma-enhanced tetraethylorthosilicate), and so on.

A bottom electrode 212 is formed in the first interlayer insulating layer 210 as shown in FIG. 9A. The bottom electrode 212 may be formed, for example, by etching of a contact hole in the interlayer insulating layer 210, followed by deposition of a material layer of the bottom electrode 212, followed by planarization (e.g. CMP) of the material layer to define the bottom electrode 212. The shape of the bottom electrode 212 is not limited. As non-limiting examples, the bottom electrode 212 may be columnar with a circular or rectangular cross-section, or the bottom electrode 212 may be annular with a ring-shaped cross-section. Further, as mentioned previously, the bottom electrode 212 may be formed of multiple layers of different materials. Non-limiting examples of the material(s) constituting the bottom electrode include one or more of Cu, Ti, TiSiX, TiN, TiON, TiAlN, TiAlON, TiSiN, TiBN, W, WSiX, WN, WON, WSiN, WBN, WCN, Ta, TaSiX, TaN, TaON, TaAlN, TaSiN, TaCN, Mo, MoN, MoSiN, MoAlN, NbN, ZrSiN, ZrAlN, Ru, CoSiX, NiSiX and conductive carbon.

Referring to FIG. 9B, a second interlayer insulating layer 220 is deposited over the first interlayer insulating layer 210. The second interlayer insulating layer 220 may, for example, be formed of SiO₂, BSG, PSB, PBSG, PE-TEOS, and so on. An etch stop layer 221 is then patterned over the second interlayer insulating layer 220. Non-limiting examples of the etch stop layer include SiN, SiON, HfO, AlO, and so on. The etch stop layer 221, which exhibits high etch-selectivity to the second interlayer insulating layer 220, it then used as an etch mask to etch a trench 222 in the second interlayer insulating layer 220. The trench 222 is etched such that a bottom wall 223 thereof exposes at least a portion of the upper surface of the bottom electrode 212. Also, as shown in the figure, sidewalls 224 of the trench 222 may be formed obliquely such that a width of the trench 222 is larger at its upper opening than at the bottom wall 223.

Next, referring to FIG. 9C, a resistive variable material layer 230 is deposited which conforms to the surface of the structure shown in FIG. 9B. That is, the resistive variable material layer 230 is deposited to conformally cover the etch stop layer 221, the sidewalls 224 of the trench 222, and the bottom wall 223 of the trench 222. The resistance variable material layer 230 may be deposited, for example, by a CVD (chemical vapor deposition) or a PVD (physical vapor deposition) process. In the example of this embodiment, the resistive variable material layer is formed of a phase-change material. Non-limiting example of suitable phase-change materials include SeSbTe, GeTeAs, SnTeSn, GeTe, SbTe, SeTeSn, GeTeSe, SbSeBi, GeBiTe, GeTeTi, InSe, GaTeSe, and InSbTe. In addition, the resistance variable material layer 130 may be doped, for example, with C, N, Si and/or O.

Next, still referring to FIG. 9C, a protective layer 240 is deposited on the resistance variable material layer 230. In the example of this embodiment, the protective layer 240 is deposited to conform to the topology of the resistance variable material layer 230, and thus does not completely fill the trench 222. For example, the depth of the protective layer 240 may be less than half the width of the trench in order to avoid filling the trench.

The protective layer 240 may function to prevent heat loss of a resistive variable element during operation of the fabricated resistance variable memory device. In addition, the protective layer 240 functions to protect the resistance variable material layer 230 from process damage during subsequent steps in the fabrication process. For example, the protection layer 240 may protect the resistance variable material layer 230 from etch conditions and/or oxygen exposure (i.e., oxygen diffusion) during subsequent processes.

Non-limiting examples of a material of the protective layer 240 include silicon nitride, silicon carbon nitride, carbon nitride and/or carbon. In one specific example, the protective layer 240 is formed by PE-CVD (plasma enhanced CVD) of silicon nitride at a temperature of about 380° C. to about 400° C. As described above, the resistance variable material layer 230 may be doped with C, N, Si and/or O. In this case, it is noted that the volatile temperature of the doped material is higher than that of a non-doped material.

Next, referring to FIG. 9D, the gap left in the trench 222 by the protective layer pattern 241 is filled with an insulating material 250. This can be accomplished, for example, by blanket deposition of an insulating material followed by a planarization process. Non-limiting examples of the blanket deposited insulating material include silicon oxide such as HDP (high density plasma) oxide, PE-TEOS (plasma-enhanced tetraethylorthosilicate), BPSG (borophosphosilicate glass), USG (undoped silicate glass), FOX (flowable oxide), HSQ (hydrosilsesquioxane) and SOG (spin on glass). Planarization may be achieved, for example, by CMP (chemical mechanical polishing) or by an etch-back process. In either case, the etch stop layer 221 may be utilized as a removal stop layer. Also, during planarization, any portions of protective layer pattern 241 and the resistance variable material layer 231 on or above the etch stop layer 221 are removed to define a structure having a top planar surface as shown in FIG. 9D. In this manner, the resistance variable layer patterns 231 of FIG. 6 are formed.

Although not shown in the figures, the planarization process may be followed by plasma treatment using an inert gas. Non-limiting examples of the inert gas include Ar, He, Ne, Kr and/or Xe. Also, a sputtering process may be executed after planarization to remove any damaged or oxidized portions of the resistive variable layer pattern 231.

Next, referring to FIG. 9E, a barrier material layer and an electrode material layer are deposited and patterned using conventional techniques (e.g., deposition, masking and etching) to define a top electrode 261 and a barrier layer 263. Non-limiting examples of the material of the top electrode 261 include Ti, TiSiX, TiN, TiON, TiW, TiAlN, TiAlON, TiSiN, TiBN, W, WSiX, WN, WON, WSiN, WBN, WCN, Ta, TaSiX, TaN, TaON, TaAlN, TaSiN, TaCN, Mo, MoN, MoSiN, MoAlN, NbN, ZrSiN, ZrAlN, Ru, CoSi, NiSi, conductive carbon, and Cu.

The barrier layer 263 may function as an adhesive layer, and may also prevent inter-diffusion between the top electrode 261 and the underlying layers, such as the underlying resistive variable layer pattern 231. Non-limiting material examples of the barrier layer 263 include TiN, TiW, TiCN, TiAlN, TiSiC, TaN, TaSiN, WN, MoN and CN.

In addition, in the case where the resistive variable layer patterns 231 are formed of a phase-change material, such as a GST (or chalcogenide) material, the barrier layer 263 can also be formed to include a phase-change material which is the same as or different than the material of the resistive variable layer patterns 231. This can have the advantage of compensating for any damage to the resistive variable layer patterns 231 that may have occurred during planarization of the insulating layer 250 described previously. For example, the barrier layer 263 can include a stacked structure of a GST material layer and a conductive layer.

Next, as shown in FIG. 9F, a third interlayer insulating layer 270 is deposited, contact plugs 271 are formed in the interlayer insulating layer 270, and conductive bit lines BL are formed so as to electrically contact the contact plugs 271. Techniques and materials that may be utilized to form these elements are well-known to those skilled in the art. As shown in FIGS. 6 and 7, the bit lines BL extend lengthwise in a direction parallel with the resistance variable layer patterns 231.

Various examples of real-world applications of the resistance variable memory devices described above are presented next. These applications are collectively referred to herein as memory systems.

FIG. 10 illustrates an apparatus including a resistance variable memory device adopting one or more inventive concepts described herein. As shown, the apparatus includes a memory 510 and a memory controller 520. The memory 510 may include a resistance variable memory device as described herein. The memory controller 520 may supply an input signal to control an operation of the memory 510. For example, the memory controller 520 may supply a command language and an address signal. The memory controller 520 may control the memory 510 based on a received control signal.

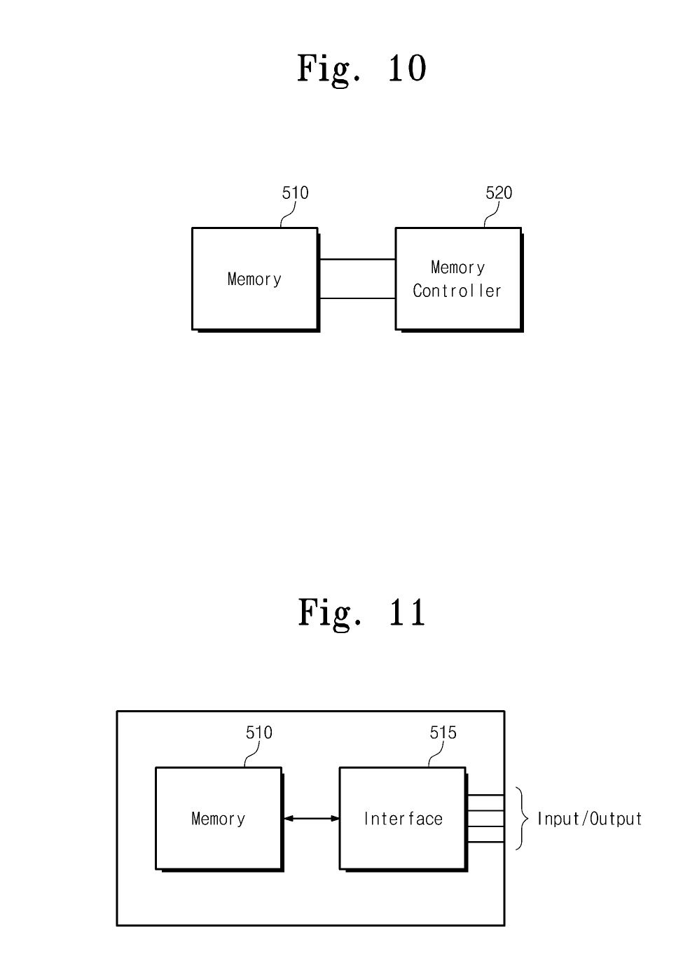

FIG. 11 illustrates an apparatus including a resistance variable memory device adopting one or more inventive concepts described herein. As shown, the apparatus includes a memory 510 connected to an interface 515. The memory 510 includes a resistance variable memory device as described herein. The interface 515 may provide, for example, an external input signal. For example, the interface 515 may provide a command language and an address signal. The interface 515 may control the memory 510 based on a control signal which is generated from an outside and received.

FIG. 12 illustrates an apparatus including a resistance variable memory device adopting one or more inventive concepts described herein. As shown, the apparatus is similar to the apparatus of FIG. 10, except that the memory 510 and the memory controller 520 are embodied by a memory card 530. For example, the memory card 530 may be a memory card satisfying a standard for compatibility with electronic appliances, e.g., digital cameras, personal computers or the like. The memory controller 520 may control the memory 510 based on a control signal which the memory card receives from a different device, for example, an external device.

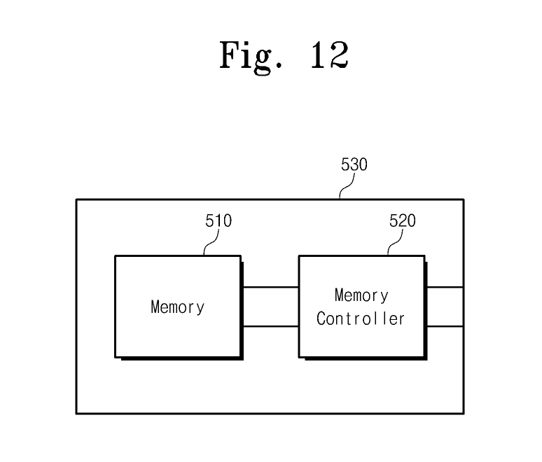

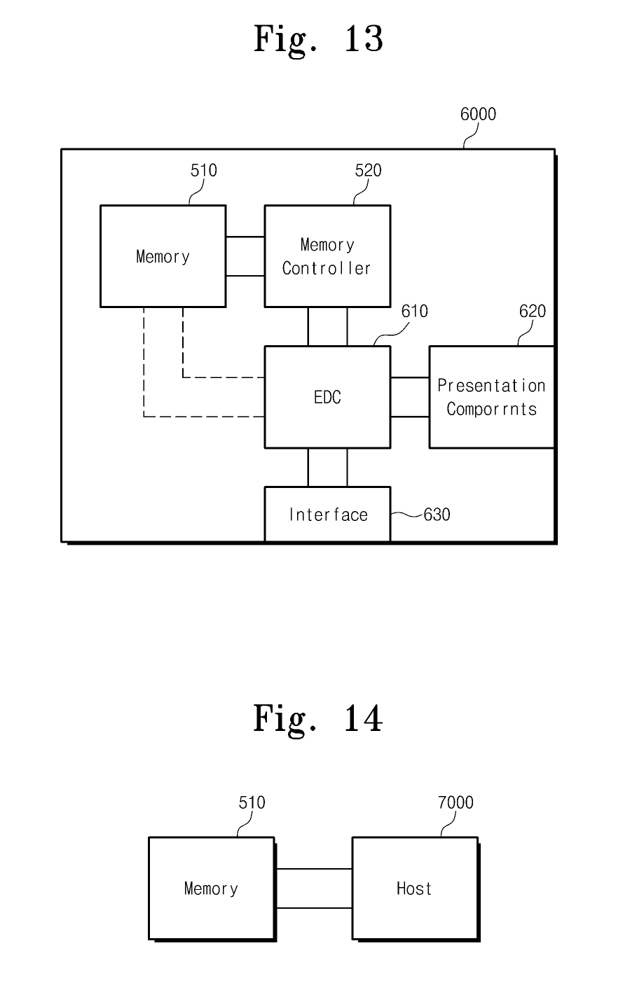

FIG. 13 illustrates a mobile device 6000 including a resistance variable memory device adopting one or more inventive concepts described herein. The mobile device 6000 may be an MP3, a video player, a video, audio player or the like. As illustrated in the drawing, the mobile device 6000 includes the memory 510 and the memory controller 520. The memory 510 may include a resistance variable memory device as described herein. The mobile device 6000 may include an encoder and decoder EDC 610, a presentation component 620, and an interface 630. Data such as videos and audios may be exchanged between the memory 510 and the encoder and decoder EDC 610 via the memory controller 520. As indicated by a dotted line, data may be directly exchanged between the memory 510 and the encoder and decoder EDC 610. EDC 610 may encode data to be stored in the memory 510. For example, EDC 610 may encode audio data into an MP3 file and store the encoded MP3 file in the memory 510. Alternatively, EDC 610 may encode MPEG video data (e.g., MPEG3, MPEG4, etc.) and store the encoded video data in the memory 510. Also, EDC 610 may include a plurality of encoders that encode different data type according to different data formats. For example, EDC 610 may include an MP3 encoder for audio data and an MPEG encoder for video data. EDC 610 may decode output data from the memory 510. For example, EDC 610 may decode audio data output from the memory 510 into an MP3 file. Alternatively, EDC 610 may decode video data output from the memory 510 into an MPEG file. Also, EDC 610 may include a plurality of decoders that decode a different type of data according to a different data format. For example, EDC 610 may include an MP3 decoder for audio data and an MPEG decoder for video data. Also, EDC 610 may include only a decoder. For example, previously encoded data may be delivered to EDC 610, decoded, and then delivered to the memory controller 520 and/or the memory 510. EDC 610 may receive data to encode or previously encoded data via the interface 630. The interface 630 may comply with a well-known standard, e.g., USB, firewire, etc. The interface 630 may include one or more interfaces, e.g., a firewire interface, a USB interface, etc. The data provided from the memory 510 may be output via the interface 630. The presentation component 620 may represent data decoded by the memory 510 and/or EDC 610 such that a user can perceive the decoded data. For example, the presentation component 620 may include a display screen displaying a video data, etc., and a speaker jack to output an audio data.

FIG. 14 illustrates an apparatus including a resistance variable memory device adopting one or more inventive concepts described herein. As shown, the memory 510 may be connected to a host system 7000. The memory 510 includes a resistance variable memory as described herein. The host system 7000 may be a processing system, e.g., a personal computer, a digital camera, etc. The memory 510 may be a detachable storage medium, e.g., a memory card, a USB memory, or a solid-state driver SSD. The host system 7000 may provide an input signal, e.g., a command language and an address signal, controlling an operation of the memory 510.

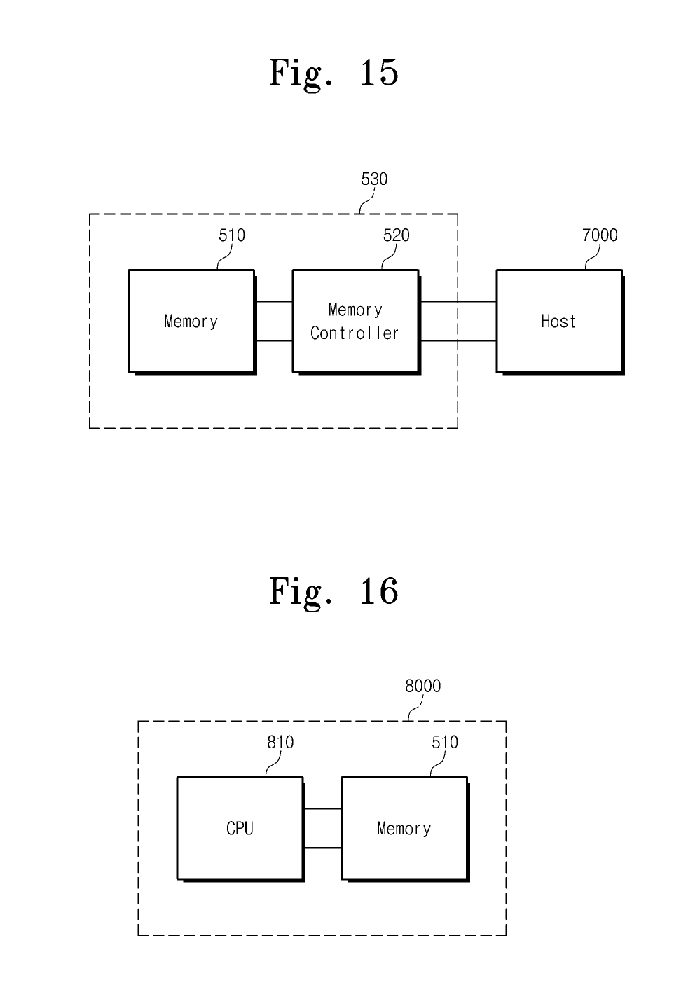

FIG. 15 illustrates an apparatus including a resistance variable memory device adopting one or more inventive concepts described herein. In this example, the host system 7000 may be connected to the memory card 530. The host system 7000 may supply a control signal to the memory card 530, enabling the memory controller 520 to control operation of the memory 510.

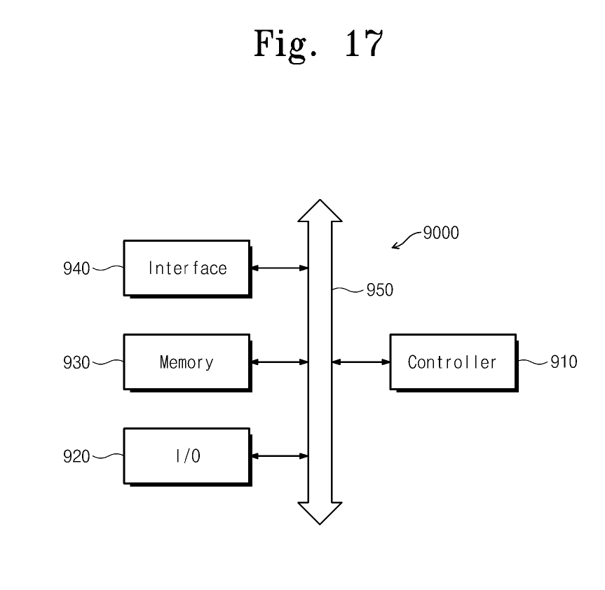

FIG. 16 illustrates an apparatus including a resistance variable memory device adopting one or more inventive concepts described herein. As illustrated, the memory 510 may be connected with a central processing unit CPU 810 of a computer system 8000. For example, the computer system 8000 may be a personal computer, a personal data assistant, etc. The memory 510 may be connected to the CPU 810 via a bus.

FIG. 17 illustrates an apparatus including a resistance variable memory device adopting one or more inventive concepts described herein. As shown in FIG. 17, the apparatus 9000 may include a controller 910, an input/output unit 920, e.g., a keyboard, a display or the like, a memory 930, and an interface 940. The respective components constituting the apparatus may be connected to each other via a bus 950. The controller 910 may include at least one microprocessor, digital processor, microcontroller, or processor. The memory 930 may store a command executed by data and/or the controller 910. The interface 940 may be used to transmit data from a different system, for example, a communication network, or to a communication network. The apparatus 9000 may be a mobile system, e.g., a PDA, a portable computer, a web tablet, a wireless phone, a mobile phone, a digital music player, a memory card or a different system that can transmit and/or receive information.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A resistance variable memory device comprising:
at least one bottom electrode;
a first insulating layer containing a trench which exposes the at least one bottom electrode;
a resistance variable material layer including respective first and second portions located on opposite sidewalls of the trench, respectively, wherein the first and second portions of the resistance variable material layer are electrically connected to the at least one bottom electrode;
a protective layer covering the resistance variable material layer within the trench; and
a second insulating layer located within the trench and covering the protective layer within the trench.

2. The resistance variable memory device of claim 1, wherein the resistance variable material layer is a phase-change material layer.

3. The resistance variable memory device of claim 1, wherein the at least one bottom electrode includes a first bottom electrode and a second bottom electrode, wherein the first and second portions of the resistance variable layer are electrically isolated from one another and electrically connected to the first and second bottom electrodes, respectively, and
wherein the first and second portions of the resistance variable material layer are storage elements of respective first and second memory cells.

4. The resistance variable memory device of claim 3, wherein the resistance variable material layer is a phase-change material layer, and wherein the first and second memory cells are phase-change memory cells.

5. The resistance variable memory device of claim 3, wherein each of the first and second portions of the resistance variable material layer have a substantially L-shaped cross-section.

6. The resistance variable memory device of claim 3, wherein the first and second portions of the resistance variable material layer extend lengthwise in the trench to cross over a plurality of respective first and second bottom electrodes and to form a plurality respective first and second memory cells.

7. The resistance variable memory device of claim 1, wherein protective layer comprises at least one of silicon nitride, silicon carbon nitride, carbon nitride and carbon.

8. The resistance variable memory device of claim 3, wherein the protective layer comprises spaced apart first and second protective layers respectively covering the first and second portions of the resistance variable material layer.

9. The resistance variable memory device of claim 8, wherein first and second protective layers comprise at least one of silicon nitride, silicon carbon nitride, carbon nitride and carbon.

10. The resistance variable memory device of claim 1, wherein the at least one electrode comprises a single electrode, and wherein the resistance variable material layer is contiguous between the first and second portions a storage element a phase-change memory cell.

11. The resistance variable memory device of claim 1, further comprising at least one top electrode electrically contacting the first and second portions of the resistance variable material layer.

12. The resistance variable memory device of claim 11, wherein the top electrode includes a barrier layer.

13. The resistance variable memory device of claim 12, wherein the resistance variable material layer includes a phase-change material, and wherein the barrier layer includes a phase-change material.

14. A resistance variable memory device, comprising a plurality of word lines, a plurality of bit lines, and an array of resistance variable memory cells each electrically connected between a respective word line and a respective bit line, wherein each of the memory cells comprises:
a resistance variable material layer located on opposite sidewalls of a trench formed in a material layer interposed between the word lines and bit lines;
a protective layer covering the resistance variable material layer within the trench;
an insulating layer located within the trench and covering the protective layer within the trench.

15. The resistance variable memory device of claim 14, wherein the resistance variable material layer is a phase-change material layer.

16. The resistance variable memory device of claim 15, further comprising a bottom electrode electrically connected between each memory cell and a word line, and
wherein the resistance variable material layer includes first and second portions on the opposite sidewalls of the trench that are electrically isolated from one another and electrically connected to respective first and second bottom electrodes, and
wherein the first and second portions of the resistance variable material layer are storage elements of respective first and second memory cells.

17. The resistance variable memory device of claim 16, wherein each of the first and second portions of the resistance variable material layer have a substantially L-shaped cross-section.

18. The resistance variable memory device of claim 17, wherein the first and second portions of the resistance variable material layer extend lengthwise in the trench to cross over a plurality of respective first and second bottom electrodes and to form a plurality respective first and second memory cells.

19. A storage system comprising the resistance variable memory device of claim 14.

20. A method of forming a resistance variable memory cell, comprising:
providing a first insulating layer which includes first and second electrodes;
forming a second insulating layer on the first insulating layer;
forming a trench within the second insulating layer so as to at least partially expose the first and second electrodes;
forming a resistance variable material layer within the trench such that the resistance variable material layer electrically contacts the first and second bottom electrodes and is located on opposite sidewalls and a bottom wall of the trench;
forming a protective layer over the resistance variable material layer;
removing a portion of the protective layer to define spaced apart first and second protective layer portions located over the resistance variable material layer at the opposite sidewall walls of the trench, wherein a portion of the resistance variable material layer on the bottom wall of the trench is exposed between the first and second protective layer portions;
removing the exposed portion of the resistance variable material layer to define first and second resistance variable material layer portions of the opposite sidewalls of the trench;
filling the trench with a third insulating layer; and
forming first and second top electrodes which are electrically connected to the first and second resistance variable material layer portions.
